(19) United States
(12) Patent Application Publication
(10) Pub. No.: US 2007/0166628 A1
(43) Pub. Date: Jul. 19, 2007

(54) MASK AND DISPLAY SUBSTRATE MANUFACTURED USING THE MASK AND DISPLAY PANEL HAVING THE DISPLAY SUBSTRATE

(76) Inventor: Young-Bae Jung, Hwaseong-si (KR)

Correspondence Address: Frank Chau, Esq.;F. CHAU & ASSOCIATES, LLC, 130 Woodbury Road, Woodbury, NY, 11797, US

(21) Appl. No.: 11/563,360

(22) Filed: Nov. 27, 2006

(30) Foreign Application Priority Data
Jan. 13, 2006 (KR) 2006-4012

(51) Int. Cl. G02F 1/1335; G03F 1/00

(52) U.S. Cl. 430/5; 349/65

(57) ABSTRACT

A mask used in manufacturing a display substrate, including a transmission region and a reflection region, includes a transparent substrate, a translucent layer and a light blocking layer. The transparent substrate transmits light. The translucent layer is on the transparent substrate and transmits a portion of the light. The light blocking layer includes a first pattern part and a second pattern part. The first pattern part corresponds to the reflection region to partially transmit the portion of the light having passed through the translucent layer, The second pattern part corresponds to the transmission region to diffract the portion of the light having passed through the translucent layer.

### CROSS-REFERENCE TO RELATED APPLICATIONS

The present application claims priority from Korean Patent Application No. 2006-04012>filed on Jan. 13, 2006, the disclosure of which is hereby incorporated herein by reference in its entirety.

### BACKGROUND OF THE INVENTION

1. Technical Field

The present invention relates to a mask, and, more particularly, to a mask used in manufacturing a display substrate that exhibits improved image display quality, a display substrate manufactured using the mask, a method of manufacturing the display substrate and a display panel having the display substrate,

2. Discussion of the Related Art

A liquid crystal display (LCD) device can be classified into a transmissive type LCD device, a reflective type LCD device and a transflective LCD device based on the light source and corresponding methods of using the light.

For example, a transflective LCD device includes an LCD panel and a backlight assembly. The LCD panel displays an image based on a backlight and an externally provided light. The backlight assembly supplies the LCD panel with the backlight. The LCD panel includes a plurality of pixels to display the image. Each of the pixels includes a transmission region and a reflection region. The backlight passes through the transmission region to display the image. The externally provided light is reflected from the reflection region to display the image. The externally provided light is reflected from a reflecting electrode that includes metal, and passes two times through a liquid crystal layer and a color fitter layer. Thus, the reflection region has a different light path from the transmission region so that color purity uniformity and luminance is decreased, thereby towering an image display quality. Therefore, to decrease the difference between the light paths of the reflection region and the transmission region, an overcoating layer having a predetermined thickness is formed in the reflection region of the LCD panel to adjust cell gaps of the reflection region and the transmission region. The overcoating layer may be formed on an array substrate having the reflecting electrode or on a color filter substrate having the color filter.

However, the cell gap of the transmission region is irregular, and a stepped portion is formed between the reflection region and the transmission region, thereby reducing the image display quality.

### SUMMARY OF THE INVENTION

Embodiments of the present invention provide a mask used in manufacturing a display substrate having improved image display quality, a display substrate manufactured using the mask, a method of manufacturing the display substrate, and a display panel having the display substrate.

A mask for manufacturing a display substrate, including a transmission region and a reflection region, in accordance with an embodiment of the present invention, includes a transparent substrate, a translucent layer and a light blocking layer. The transparent substrate transmits light. The translucent layer is on the transparent substrate and transmits a portion of the light. The light blocking layer includes a first pattern part and a second pattern part. The first pattern part corresponds to the reflection region to partially transmit the portion of the light having passed through the translucent layer. The second pattern part corresponds to the transmission region to diffract the portion of the light having passed through the translucent layer.

A display substrate in accordance with an embodiment of the present invention includes a pixel, an overcoating layer, a transparent electrode and a reflecting electrode. The pixel includes a switching element electrically connected to gate and source lines. A transmission region and a reflection region are defined in the pixel. The overcoating layer is on the switching element, and includes a recess, a protrusion and a flat portion. The recess is in the reflection region, and has a first height. The protrusion is also in the reflection region, and has a second height greater than the first height. The flat portion is in the transmission region, and a height of the flat portion is between the first height and the second height. The transparent electrode is on the flat portion of the overcoating layer to transmit a first light, The reflecting electrode is on the recess and the protrusion to reflect a second light.

A method of manufacturing a display substrate, in accordance with an embodiment of the present invention, includes forming a switching element on a base substrate, wherein the switching element is electrically connected to gate and source lines. An overcoating layer including a photoresist material is formed on the base substrate having the switching element. A recess having a first height, a protrusion having a second height and a flat portion having a height between the first and second heights are formed. The recess and the protrusion are in a first region of the overcoating layer, and the flat portion is in a second region of the overcoating layer. A transparent electrode is formed in the second region on the overcoating layer, A reflecting electrode is formed in the first region on the overcoating layer.

A display panel in accordance with an embodiment of the present invention includes an array substrate and an opposite substrate, The array substrate includes a pixel and an overcoating layer. The pixel is defined by gate and source lines, and a transmission region and a reflection region are defined in the pixel. The overcoating layer includes a recess, a protrusion and a flat portion. The recess is in the reflection region, and has a first height. The protrusion is in the reflection region, and has a second height greater than the first height. The flat portion is in the transmission region, and a height of the flat portion is between the first height and the second height. The opposite substrate is combined with the array substrate. A liquid crystal layer can be interposed between the opposite and array substrates.

According to the embodiments of the present invention, a stepped portion between the transmission region and the reflection region is removed to prevent, for example, light leakage and rubbing defects. In addition, the overcoating layer corresponding to the transmission region has a substantially flat surface so that liquid crystals in the transmission region are uniformly arranged, Therefore, an image display quality is improved.

### BRIEF DESCRIPTION OF THE DRAWINGS

Exemplary embodiments of the present invention can be understood in more detail from the following descriptions taken in conjunction with the accompanying drawings, in which.

FIG. 1 is a plan view illustrating a transflective LCD device in accordance with an embodiment of the present invention;

FIG. 2 is an enlarged plan view illustrating the transflective LCD device shown in FIG. 1;

FIG. 3 is a cross-sectional view taken along a line I-I′ shown in FIG. 2; and

FIGS. 4 to 10 are cross-sectional views for illustrating a method of manufacturing the display substrate shown in FIG. 3 in accordance with an embodiment of the present invention.

### DESCRIPTION OF EXEMPLARY EMBODIMENTS

Exemplary embodiments of the present invention are described more fully hereinafter with reference to the accompanying drawings. This invention may, however, be embodied in many different forms and should not be construed as limited to the embodiments set forth herein. In the drawings, the size and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present.

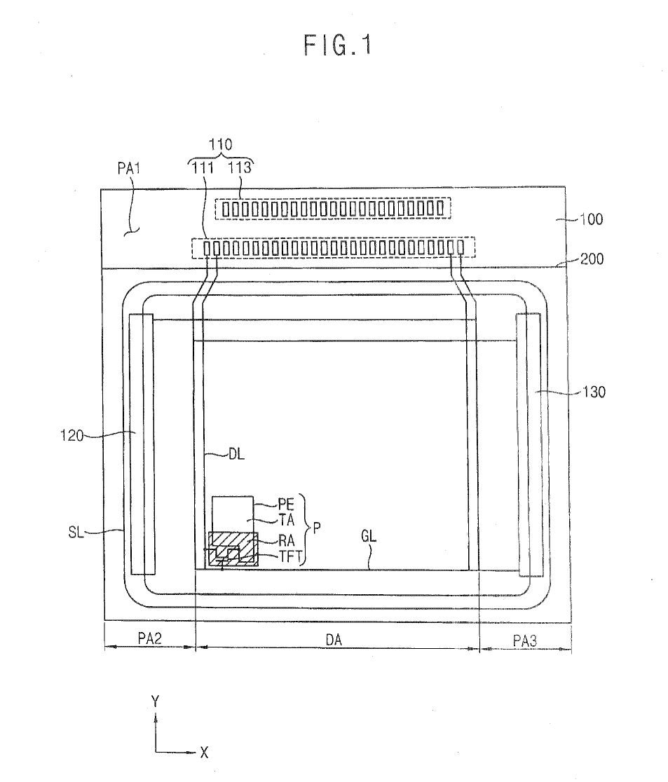

FIG. 1 is a plan view illustrating a transflective LCD device in accordance with an embodiment of the present invention.

Referring to FIG. 1, the transflective LCD panel includes a display substrate 100 an opposite substrate 200 and a liquid crystal layer (not shown) interposed between the display substrate 100 and the opposite substrate 200.

A display region DA, a first peripheral region PA1, a second peripheral region PA2 and a third peripheral region PA3 are defined on the display substrate 100.

A plurality of source lines DL and a plurality of gate lines GL are formed in the display region DA. The source lines DL are extended in a first direction. The gate lines GL are extended in a second direction that crosses the first direction. For example, the gate lines GL are substantially perpendicular to the data lines DL.

A plurality of pixels P that is defined by the source and gate lines DL and GL is formed in the display region DA. A switching element TFT and a pixel electrode PE are formed in each of the pixels P.

Each of the pixels P includes a reflection region RA and a transmission region TA. A reflecting electrode is formed in the reflection region RA, and is not formed in the transmission region TA. A first light from a rear surface of the transflective LCD panel passes through the transmission region TA. The first tight may be an internally provided tight. A second light from a front surface of the transflective LCD panel is reflected from the reflection region TA. The second light may be an externally provided tight, such as natural light.

A pad member 110 that transmits driving signals to the display region DA is formed in the first peripheral region PA1. The pad member 110 includes a first pad part 111 and a second pad part 113. The driving signals from a flexible printed circuit board are applied to the first pad part 111. A driving chip, which generates data voltages based on the driving signals, is on the second pad part 113. The data voltages are applied to the source lines DL.

A first gate circuit 120 is in the second peripheral region PA2, and applies gate signals to odd-numbered gate lines GL.

A second gate circuit 130 is in the third peripheral region PA3, and applies gate signals to even-numbered gate lines GL. Alternatively, a single gate circuit (not shown) may be in the second peripheral region PA or the third peripheral region PAS to apply the gate signals to both the odd and even-numbered gate lines GL.

A seal line region SL, in which a sealant is formed, is defined in a peripheral region that, for example, includes the first, second and third peripheral regions PA1, PAM and PA3 that surround the display region DA. The sealant is used to combine display substrate 100 with the opposite substrate 200.

The opposite substrate 200 includes a plurality of color filter patterns and a common electrode. The color filter patterns correspond to the pixels P, respectively. The pixel electrodes PE correspond to the common electrode. The color filter patterns include a red (R) color filter, a green (G) color filter and a blue (B) color filter. The common electrode defines liquid crystal capacitors formed by the pixels P of the LCD panel with the pixel electrodes PE and the liquid crystal layer. A common voltage VCOM is applied to the common electrode.

According to an embodiment, the sealant is formed in the seal line region SL, and the display substrate 100 is combined with the opposite substrate 200. Liquid crystals are injected into a space between the display substrate 100 and the opposite substrate 200 to form the liquid crystal layer.

An overcoating layer may be formed on the display substrate 100 or the opposite substrate 200 to control the cell gap in the reflection region RA and the transmission region TA of the transflective LCD device. The overcoating layer may be formed in the reflection region RA.

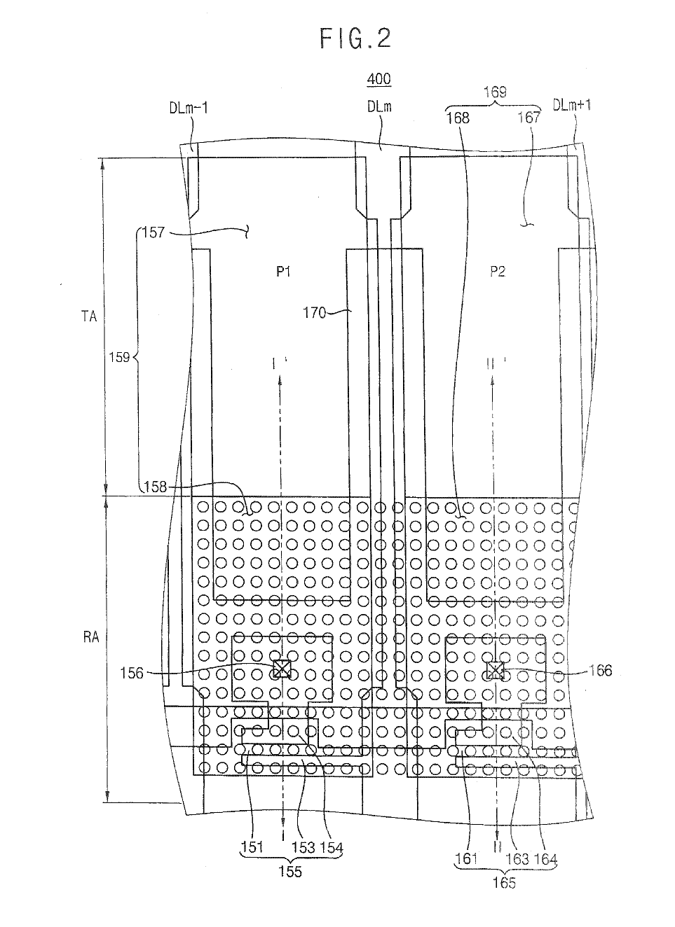

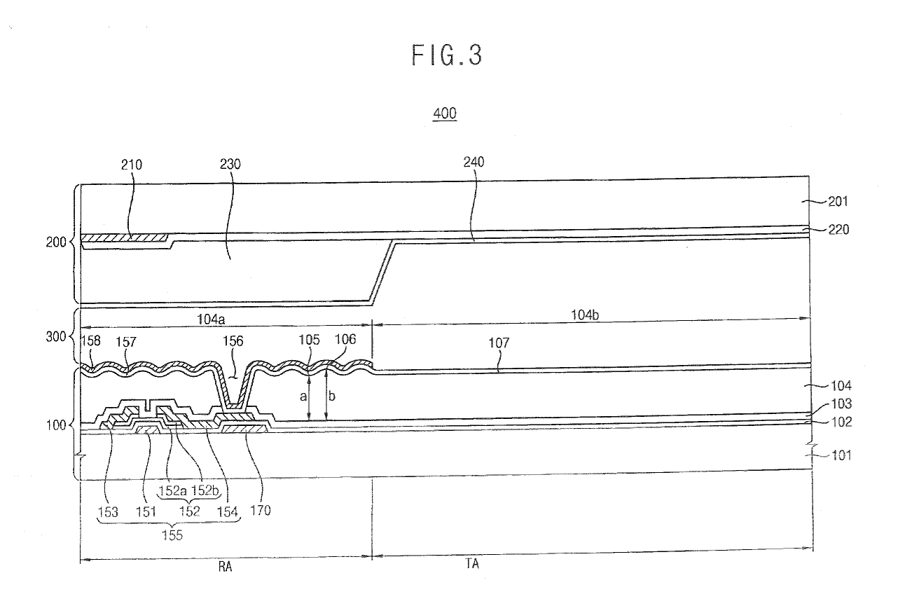

FIG. 2 is an enlarged plan view illustrating the transflective LCD device shown in FIG. 1. FIG. 3 is a cross-sectional view taken along a line I-I′ shown in FIG. 2.

Referring to FIGS. 2 and 3, the transflective LCD panel 400 includes a plurality of pixels, including, for example, a first pixel P1 and a second pixel P2 that is adjacent to the first pixel P1. The first pixel P1 is defined by adjacent source and gate lines DLm−1, DLm, GLn−1 and GLn.

The first pixel P1 includes a first switching element 155 and a first pixel electrode 159. The first switching element 155 is on a first base substrate 101. The first pixel electrode 159 is electrically connected to the first switching element 155. The first pixel electrode 159 includes a first transparent electrode 157 and a first reflecting electrode 158. The first pixel P1 is divided into the transmission region TA and the reflection region RA, wherein the reflection region RA includes the first reflecting electrode 158 and the transmission region TA does not include the first reflecting electrode 158.

The first pixel P1 displays a color image using the color filter layer 220 of the opposite substrate 200. The color fitter layer 220 includes the red, green and blue color filter patterns, and each of the color filter patterns correspond to respective pixel parts, for example, pixels P1 and P2, respectively.

The second pixel P2 is defined by adjacent source and gate lines DLm, DLm+1, GLn−1 and GLn.

The second pixel P2 includes a second switching element 165 and a second pixel electrode 169. The second switching element 165 is formed on the first base substrate 101. The second pixel electrode 169 is electrically connected to the second switching element 165. The second pixel P2 is divided into a transmission region TA and a reflection region RA defined by the presence or lack thereof of second reflecting electrode 168.

The second pixel P2 displays a color image using the color filter layer 220 of the opposite substrate 200.

A storage common line 170 that is electrically connected to the first and second pixels P1 and P2 is formed on the first base substrate 101. For example, referring to FIG. 2, the storage common time 170 may have a branch shape to cover the source lines DLm−1, DLm and DLm+1.

The display substrate 100 of the transflective LCD panel includes the first base substrate 101.

A gate metal pattern is formed on the first base substrate 101. The gate metal pattern includes gate electrodes 151 and 161 of the switching elements 155 and 165, the storage common line 170 and the gate lines GLn−1 and GLn.

A gate insulating layer 102 is formed on the first base substrate 101 to cover the gate metal pattern. An amorphous silicon layer 152a and an n+ amorphous silicon layer 152b are formed on the gate insulating layer 102, in sequence, to form a channel layer 152. n+ impurities may be implanted on an upper portion of the amorphous silicon layer 152 in situ to form the n+ amorphous silicon layer 152b. A channel layer for the second switching element 165 may be also formed.

A source metal pattern is formed on the channel layer 152. The source metal pattern includes source electrodes 153 and 163 of the switching elements 155 and 165, drain electrodes 154 and 164 of the switching elements 155 and 165 and the source lines DLm−1, DLm and DLm+1.

A passivation layer 103 and a first overcoating layer 104 are formed in sequence on the base substrate having the source metal pattern. Examples of an insulating material that can be used for the passivation layer 103 include silicon nitride (SiNx), and silicon oxide (SiOx).

The first overcoating layer 104 planarizes a surface of the display substrate. The first overcoating layer 104 may be formed through a photo process using a photoresist film. Contact holes through which the drain electrodes 154 and 164 are partially exposed are formed in the passivation layer 103 and the first overcoating layer 104.

The first overcoating layer 104 includes a first region 104a and a second region 104b. The first region 104a corresponds to the reflection region RA, and an embossing pattern is formed in the first region 104a. The second region 104b corresponds to the transmission region TA, and has a flat portion 107. The embossing pattern in the first region 104a increases reflectivity of first and second reflecting electrodes 158 and 168. For example, the embossing pattern includes recesses 105 and protrusions 106. A first height ‘a’ of the recesses 105 is smaller than a second height ‘b’ of the protrusions 106.

The second region 104b has the flat portion 107 so that the liquid crystal layer 300 in the transmission region TA has a uniform cell gap, thereby improving an image display quality of a transmission mode of the transflective LCD panel 400. The height of the first overcoating layer 104 in the second region 104b may be between the first height ‘a’ of the recesses 105 and the second height ‘b’ of the protrusions 106. The average height of the first overcoating layer 104 in the first region 104a may be substantially the same as the height of the first overcoating layer 104 in the second region 104b. In FIG. 3, the height of the second region 104b is greater than the first height ‘a’ of the recesses of the first region 104a, and is smaller than the second height ‘b’ of the protrusions of the first region 104a.

In FIG. 3, the display substrate 100 does not have a stepped portion between the reflection region RA and the transmission region TA, and the cell-gap of the liquid crystal layer 300 is controlled by a stepped portion of the opposite substrate 200 facing the display substrate 100. Thus, the cell-gap of the liquid crystal layer 300 may be easily controlled. In addition, the stepped portion is only on the opposite substrate 200 so that rubbing defects of the display substrate 100 may be decreased.

The first and second pixel electrodes 159 and 169 are formed on the first overcoating layer 104 corresponding to the first and second pixels P1 and P2, respectively, For example, the first pixel electrode 159 of the first pixel P1 includes the first transparent electrode 157 and the first reflecting electrode 158.

The first transparent electrode 157 may be formed on substantially the entire of the first pixel P1. Alternatively, the first transparent electrode 157 may only be formed in the transmission region TA. The first transparent electrode 157 includes a transparent conductive material. Examples of the transparent conductive material that can be used for the first transparent electrode 157 include indium tin oxide (ITO), and indium zinc oxide (IZO).

A first reflecting electrode 158 is formed on the first transparent electrode 157. The first reflecting electrode 158 includes a highly reflective material. Examples of the highly reflective material that can be used for the first reflecting electrode 158 include aluminum, and aluminum-neodymium alloy. The transmission region TA and the reflection region RA of the first pixel P1 are defined by the absence and presence of the first reflecting electrode 158, respectively.

The first reflecting electrode 158 is in the first region 104a of the first overcoating layer 104, and has the embossed pattern that is substantially the same as the first region 104a. The embossing pattern of the reflecting electrode 158 functions as micro-reflective lenses to guide the externally provided light that is incident into the first reflection region RA. For example, the embossing pattern may diffuse the externally provided light that is incident into the first reflection region RA. The second pixel electrode 169 of the second pixel P2 may have substantially the same structure as the first pixel electrode 159 of the first pixel P1.

A first alignment layer (not shown) to align the liquid crystals of the liquid crystal layer 300, may be formed on the first base substrate 101 having the first and second pixel electrodes 159 and 169.

The opposite substrate 200 of the transflective LCD panel 400 includes a second base substrate 201.

A black matrix 210 is formed on the second base substrate 201. The black matrix 210 may be formed on regions defined by the source and gate lines DLm−1 DLm, DLm+1, GLn−1 and GLn.

The color filter layer 220 is formed on the second base substrate 201 having the black matrix 210. The color filter layer 220 includes the blue, green and red color filter patterns, and the red, green and blue color filter patterns correspond to respective pixels, for example, pixels P1 and P2, respectively.

A second overcoating layer 230 is formed on the color filter layer 220 corresponding to the reflection region RA. The second overcoating layer 230 controls the cell-gaps of the transmission region TA and the reflection region RA so that the cell-gap of the transmission region TA is about two times of the cell-gap of the reflection region RA. The second overcoating layer 230 forms a dual cell-gap in the LCD panel 400. Thus, the externally provided light reflected from the reflection region RA has substantially the same path length as the internally provided light passing through the transmission region TA.

In each of the pixels P1 and P2, the second overcoating layer 230 in the transmission region TA in each of the pixels P1 and P2 has a different height from the second overcoating layer 230 in the reflection region RA so that the LCD panel 400 may have a multi cell-gap. Also the second overcoating layer may be omitted from the transmission region TA, and formed only in the reflection region RA.

A common electrode layer 240 is formed on the second overcoating layer 230. A second alignment layer (not shown) may be formed on the common electrode layer 240.

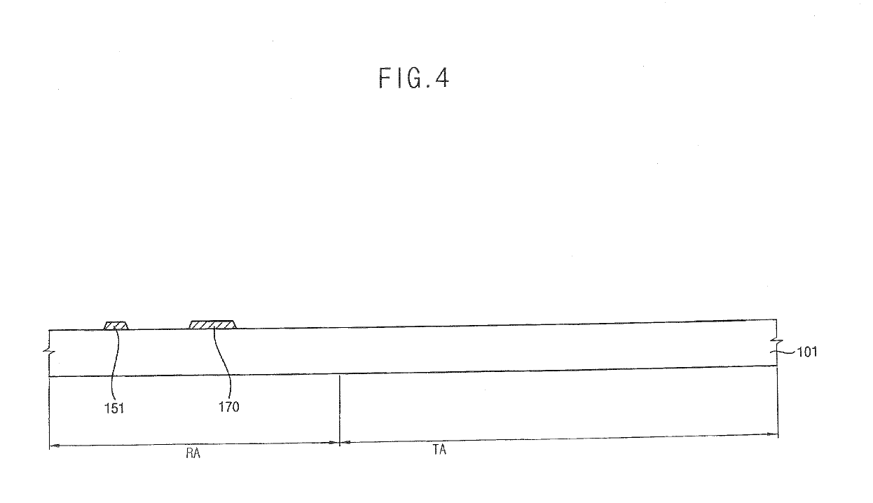

FIGS. 4 to 10 are cross-sectional views for illustrating a method of manufacturing a display substrate shown in FIG. 3.

Referring to FIGS. 1 and 4, a metal layer (not shown) is formed on the first base substrate 101. The metal layer is patterned through a photolithography process to form the gate metal pattern including the gate lines GL, the gate electrode 151 and the storage common line 170.

Examples of metal that can be used for the metal layer include chromium, aluminum, tantalum, molybdenum, titanium, tungsten, copper, and silver, These metals can be used alone, as alloys thereof or in a combination thereof. The metal layer may be formed through a sputtering process. Alternatively, the metal layer may have a multi-layered structure.

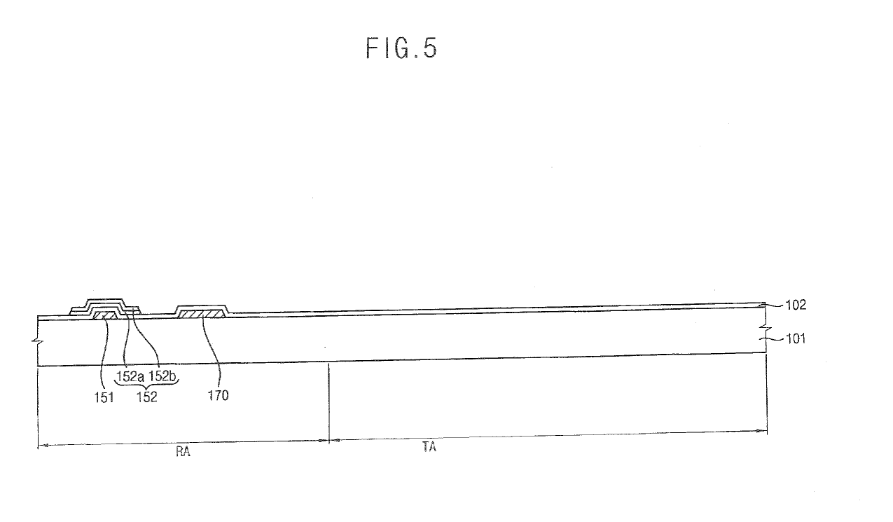

Referring to FIG. 5 the gate insulating layer 102, the amorphous silicon layer 152a and the n+ amorphous silicon layer 152b are formed on the first base substrate 101 having the gate metal pattern. The gate insulating layer 102, the amorphous silicon layer 152a and the n+ amorphous silicon layer 152b may be formed through a plasma enhanced chemical vapor deposition (PECVD) method. The gate insulating layer 102 may include, for example, a silicon nitride layer. The n+ impurities may be implanted in situ on the upper portion of the amorphous silicon layer 152a to form the n+ amorphous silicon layer 152b, The amorphous silicon layer 152a and the n+ amorphous silicon layer 152b are patterned to form the channel layer 152 corresponding to the gate electrode 151.

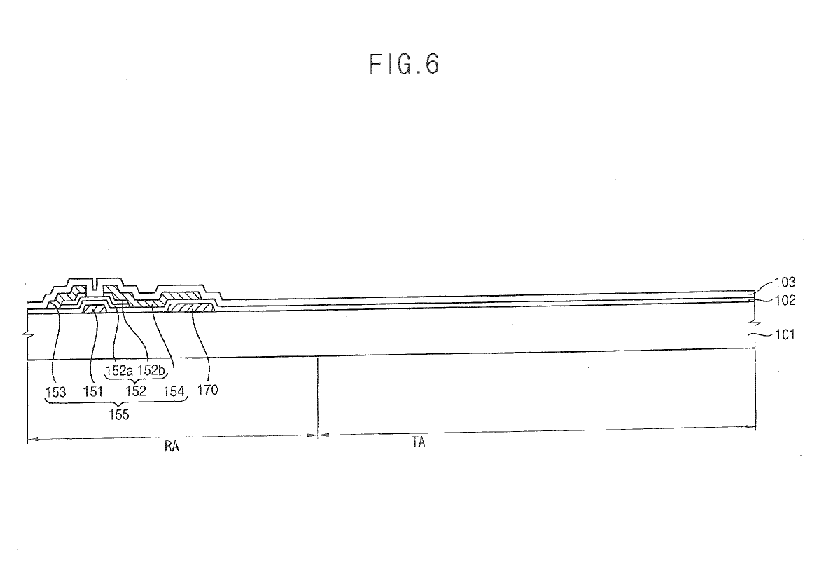

Referring to FIGS. 1 and 6, a metal layer (not shown) is deposited on the gate insulating layer 102 having the channel layer 152. Examples of metal that can be used for the metal layer deposited on the gate insulating layer 102 include chromium, aluminum, tantalum, molybdenum, titanium, tungsten, copper, and silver. These metals can be used alone, as alloys thereof or in a combination thereof. The metal layer may be deposited through a sputtering process. Alternatively, the metal layer may have a multilayered structure.

The metal layer is partially etched through a photolithography process to form the source metal pattern including the source lines DL, the source electrode 153 and the drain electrode 154 of the switching element. The source electrode 153 is spaced apart from the drain electrode 154, The drain electrode 154 is extended to partially overlap the storage common line 170.

The n+ amorphous silicon layer 152b partially exposed between the source electrode 153 and the drain electrode 154 is etched so that the amorphous silicon layer 152a between the source electrode 153 and the drain electrode 154 is exposed.

The passivation layer 103 is formed on the base substrate 101 having the partially exposed amorphous silicon layer 152a. Examples of the insulating material that can be used for the passivation layer 103 include silicon nitride and silicon oxide. The passivation layer 103 may be formed through a plasma enhanced chemical vapor deposition (PECVD) method.

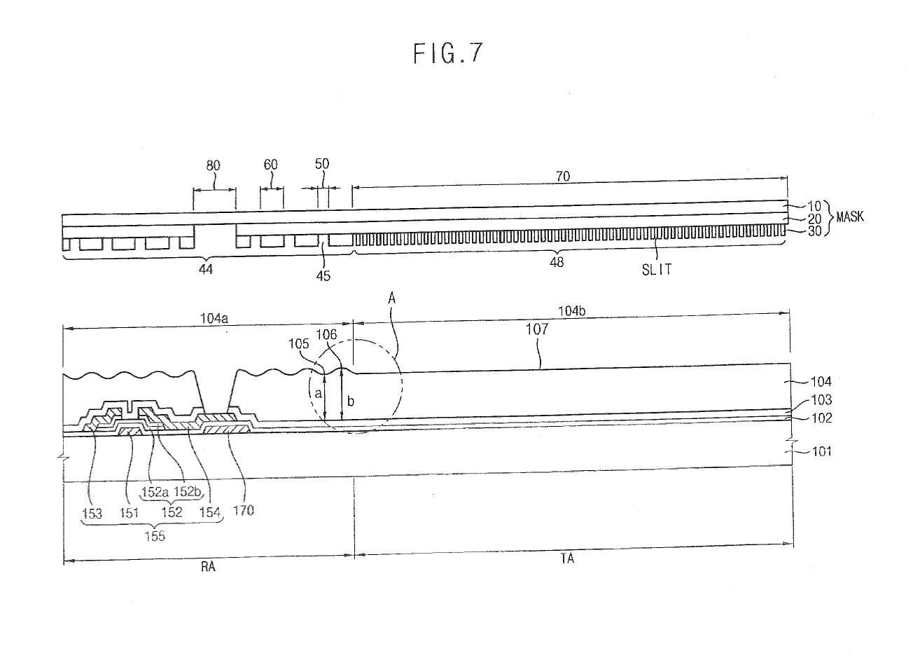

Referring to FIG. 7, a photoresist film (not shown) is formed on the passivation layer 103. The photoresist film (not shown) is exposed through a mask (MASK), and the exposed photoresist film is developed and solidified to form the first overcoating layer 104. For example, the photoresist film may include positive photoresist. When light is irradiated onto the positive photoresist, the positive photoresist may be removed through the developing process.

Referring to FIGS. 2 and 7, the first overcoating layer 104 corresponding to each of the pixels P includes the first region 104a and the second region 104b. The first region 104a corresponds to the reflection region RA that is defined by the reflecting electrode 158. The embossing pattern is formed in the first region 104a to increase the reflectivity of the reflecting electrode 158. The second region 104b corresponds to the transmission region TA, and has the flat portion 107 so that the liquid crystals are uniformly aligned in the second region 104b.

The first region 104a may be substantially simultaneously formed with the second region 104b. Light transmittance of the mask MASK is adjusted to prevent a stepped portion between the first and second regions 104a and 104b. For example, the mask MASK may have four tones.

The mask MASK includes a transparent substrate 10, a translucent layer 20 on the transparent substrate 10 and a light blocking layer 30 on the translucent layer 20.

The transparent substrate 10 includes a transparent material to transmit a substantially all of the tight incident into the transparent substrate 10. Examples of the transparent material that can be used for the transparent substrate 10 include quartz, and glass.

The translucent layer 20 includes a translucent material. For example, the translucent layer 20 may include molybdenum silicide (MoSi). Light transmittance of the translucent layer 20 may be about 25% to about 32%. Thus, the translucent layer 20 transmits a portion of the light incident into the translucent layer 20.

The light blocking layer 30 includes an opaque material. For example, the light blocking layer 30 may include chromium (Cr). The light blocking layer 30 includes a first pattern part 44 corresponding to the reflection region RA and a second pattern part 48 corresponding to the transmission region TA. The first pattern part 44 includes a plurality of first opening patterns 45. For example, a width of each of the first opening patterns 45 may be about 2 μm to about 5 μm, A portion of the light having passed through the translucent layer 20 is incident into the first opening patterns 45, and another portion of the light incident into an area between adjacent first opening patterns 45 is reflected from the light blocking layer 30.

Therefore, the first opening patterns 45 form translucent portions 50 having a tight transmittance of about 25% to about 32%. The areas of the light blocking layer 30 without the first opening pattern 45 form light blocking portions 60 having a light transmittance of about 0%. The tight blocking portion 60 may have a greater width than the first opening pattern 45.

For example, a plurality of the light blocking portions 60 and a plurality of the translucent portions 50 are alternately arranged in the first pattern part 44 by a plurality of the first opening patterns 45.

The second pattern part 48 includes a plurality of second opening patterns SLIT. For example, a width of each of the second opening patterns SLIT is about 1.0 μm to about 1.9 μm. The light having passed through the translucent layer 20 is diffracted by the second opening patterns SLIT. Thus, the second pattern part 48 defines a diffracting portion 70 on the translucent layer 20. A light transmittance of the diffracting portion 70 is about 8% to about 12%.

The mask MASK may further include an open portion 80 without the translucent layer 20 and the light blocking layer 30. For example: a light transmittance of the open portion 80 is about 100%.

The mask MASK is aligned on the first base substrate 101 having the photoresist film. The first pattern part 44 of the mask MASK corresponds to the reflection region RA. When the light is irradiated onto the mask MASK, the photoresist film corresponding to the light blocking portions 60 is not exposed, and the photoresist film corresponding to the translucent portions 50 is partially exposed. When the exposed photoresist film is developed, a thickness of the photoresist film corresponding to the translucent portions 50 is decreased. Thus, the embossing pattern is formed on the photoresist film in the reflection region RA.

For example, the recesses 105 having the first height ‘a’ and the protrusions 106 having the second height ‘b’ are alternately arranged. In FIG. 7, a difference between the first and second heights ‘a’ and ‘b’ is about 0.8 μm. The protrusions 106 correspond to the light blocking portions 60, and the recesses 105 correspond to the translucent portions 50. For example, a width of the first opening pattern 45 may be about 2 μm to about 5 μm.

The flat portion 107 is formed on the photoresist film corresponding to the transmission region TA so that the liquid crystals are uniformly aligned in the transmission region TA.

If the photoresist film corresponding to the transmission region TA were blocked by light blocking portions 60, a thickness of the unexposed photoresist film would not be decreased. As a result, the thickness of the photoresist film corresponding to the transmission region TA would be greater than the average thickness of the photoresist film corresponding to the reflection region RA. Accordingly, if the mask MASK in the transmission region TA consisted of light blocking portions 60 instead of the diffracting portion 70, a stepped portion would be formed between the reflection region RA and the transmission region TA.

In addition, if the photoresist film corresponding to the transmission region TA was exposed through the translucent layer 20 only, the photoresist film corresponding to the transmission region TA would be partially exposed. As a result, an amount of the light irradiated onto the transmission region TA would be greater than that of the light irradiated onto the reflection region RA. Accordingly, if the mask MASK in the transmission region TA consisted of the translucent layer 20, without the diffracting portion 70, the thickness of the photoresist film corresponding to the transmission region TA would be smaller than the average thickness of the photoresist film corresponding to the reflection region RA. Therefore, a stepped portion would also be formed between the reflection region RA and the transmission region TA.

However, as shown in FIG. 7, in order to adjust the amount of the light exposed into the transmission region TA and the reflection region RA, the second pattern part 48 defining the diffracting portion 70 is formed on the mask MASK corresponding to the transmission region TA. The first pattern part 44 of the mask MASK includes the translucent portions 50 having the light transmittance of about 25% to about 32% and the light blocking portions 60 having the light transmittance of about 0% so that an average amount of exposure of the first pattern part 44 is substantially the same as that of the second pattern part 48. Thus, the amount of exposure of the reflection region RA is substantially the same as the amount of exposure of the transmission region TA. Therefore, the thickness of the first overcoating layer 104 corresponding to the reflection region RA is substantially the same as that of the first overcoating layer 104 corresponding to the transmission region TA.

When the width of the second opening patterns SLIT of the diffracting portion 70 is more than about 2 μm, an embossed pattern corresponding to the second opening patterns SLIT may be formed on the surface of the photoresist film. In FIG. 7, the width of the second opening patterns SLIT is about 1.0 μm to about 1.9 μm. For example, the width of the second opening patterns SLIT may be about 1.5 μm.

In FIG. 7, the width of the second opening pattern SLIT is adjusted so that the first overcoating layer corresponding to the transmission region TA has the flat portion 107.

The exposed photoresist film is developed and solidified to form the first overcoating layer 104 having the first region 104a corresponding to the reflection region RA and the second region 104b corresponding to the transmission region TA. The recesses 105 and the protrusions 106 are formed in the first region 104a, and the flat portion 107 is formed in the second region 104b.

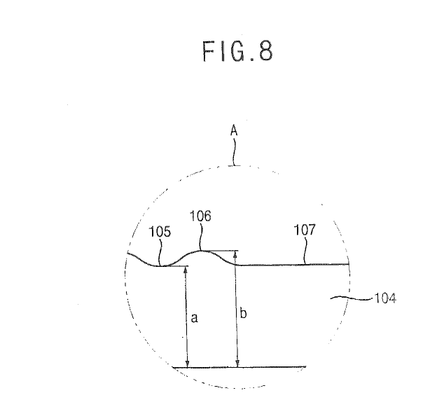

FIG. 8 is an enlarged cross-sectional view illustrating a portion ‘A’ shown in FIG. 7.

Referring to FIGS. 7 and 8, the height of the first overcoating layer 104 corresponding to the second region 104b is between the height of the recesses 105 and the height of the protrusions 106. For example, the height of the flat portion 107 of the first overcoating layer 104 in the second region 104b is between the first height ‘a’ and the second height ‘b’. Therefore a stepped portion is not formed between the first and second regions 104a and 104b.

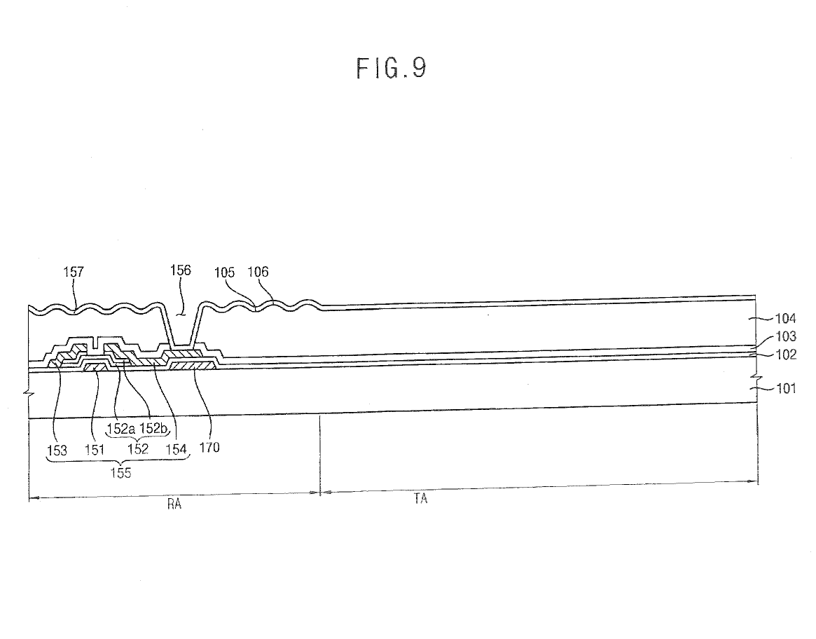

Referring to FIG. 9, a contact hole 156 through which the drain electrode 154 is partially exposed may be formed in the passivation layer 103 and the first overcoating layer 104. The contact hole 156 in the first overcoating layer 104 is formed using the open portion 80 of the mask MASK. About 100% of the light passes through the open 10) portion 80, and is irradiated onto the photoresist film so that the photoresist film corresponding to the open portion 80 is removed by a developing agent. In FIG. 7, the first region 104a, the second region 104b, the flat portion 107 and the contact hole 156 may be simultaneously formed. The passivation layer 10S corresponding to the contact hole 156 is etched using the first overcoating layer 104 as an etching mask to partially etch the passivation layer 103. Thus, the drain electrode 154 is partially exposed through the contact hole 156 that is formed through the first overcoating layer 104 and the passivation layer 103.

Referring to FIG. 9, a transparent conductive layer (not shown) is formed on the first overcoating layer 104 having the contact hole 156. Examples of a transparent conductive material that can be used for the transparent conductive layer include indium tin oxide (ITO) and indium zinc oxide (IZO). The transparent conductive layer is partially etched through a photolithography process. Thus, the transparent electrode 157 that is electrically connected to the drain electrode 154 through the contact hole 156 is formed on the first overcoating layer 104.

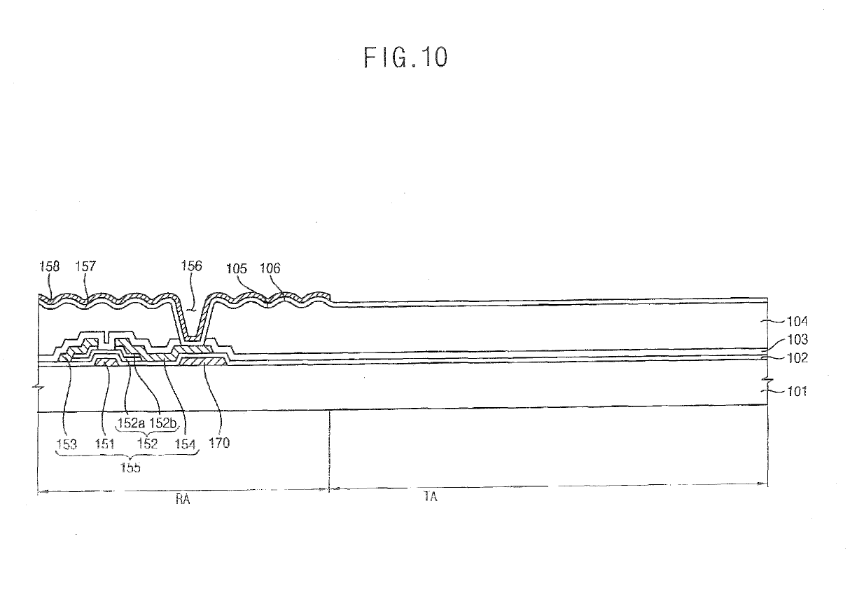

Referring to FIG. 10, a metal layer (not shown) is formed on the transparent electrode 157. The metal layer is partially removed through a photolithography process to form the reflecting electrode 158 on a portion of the transparent electrode 157. The reflecting electrode 158 may include aluminum, or aluminum-neodymium alloy. The reflecting electrode 158 is formed in the reflection region RA, and the reflecting electrode 158 is not formed in the transmission region TA.

The reflecting electrode 158 is formed along the embossing pattern having the recesses 105 and the protrusions 106 of the first overcoating layer 104 corresponding to the reflection region RA. The embossing pattern of the reflecting electrode functions as the micro-lenses to guide the externally provided light. Thus, a luminance when viewed on a plane may be improved by the embossing pattern of the reflecting electrode 158.

The transflective display substrate includes the overcoating layer including the recesses and the protrusions in the reflection region and the flat portion in the transmission region. The recesses have the first height, and the protrusions have the second height. The height of the flat portion is between the first height and the second height. Thus, the overcoating layer corresponding to the transmission region has substantially the same height as the average height of the overcoating layer corresponding to the reflection region so that a stepped portion is not formed between the transmission region and the reflection region. Thus, light leakage and rubbing defects are prevented. In addition the overcoating layer corresponding to the transmission region has the substantially flat portion so that the liquid crystals in the transmission region are uniformly arranged. Therefore, an image display quality is improved.

This invention has been described with reference to the exemplary embodiments. However, the invention is not limited to these precise embodiments, but may include modifications and variations apparent to those having skill in the art, which fall within the spirit and scope of the invention as defined by the appended claims.

What is claimed is:

1. A mask used in manufacturing a display substrate including a transmission region and a reflection region, the mask comprising:
a transparent substrate that transmits light,
a translucent layer on the transparent substrate that transmits a portion of the light; and
a light blocking layer including:
a first pattern part corresponding to the reflection region to partially transmit the portion of the light having passed through the translucent layer; and
a second pattern part corresponding to the transmission region to diffract the portion of the light having passed through the translucent layer.

2. The mask of claim 1, wherein a tight transmittance of the translucent layer is about 25% to about 32%.

3. The mask of claim 2, wherein the first pattern part has a plurality of first opening patterns, and a width of each of the first opening patterns is about 2 μm to about 5 μm.

4. The mask of claim 2, wherein the second pattern part has a plurality of second opening patterns, and a width of each of the second opening patterns is about 1.0 μm to about 1.9 μm.

5. The mask of claim 1, wherein a light transmittance of the second pattern part is about 8% to about 12%.

6. A display substrate comprising:
a pixel including a switching element electrically connected to gate and source lines, a transmission region and a reflection region being defined in the pixel;
an overcoating layer on the switching element, the overcoating layer including:
a recess in the reflection region, the recess having a first height;
a protrusion in the reflection region, the protrusion having a second height greater than the first height; and
a flat portion in the transmission region, a height of the flat portion being between the first height and the second height;
a transparent electrode on the flat portion of the overcoating layer; and
a reflecting electrode on the recess and the protrusion.

7. A method of manufacturing a display substrate comprising:
forming a switching element on a base substrate, wherein the switching element is electrically connected to gate and source lines;
forming an overcoating layer including a photoresist material on the base substrate having the switching element;
forming a recess in a first region of the overcoating layer to have a first height, a protrusion in the first region of the overcoating layer to have a second height, and a flat portion in a second region of the overcoating layer, a height of the flat portion being between the first height and the second height;
forming a transparent electrode in the second region on the overcoating layer; and
forming a reflecting electrode in the first region on the overcoating layer.

8. The method of claim 7, wherein the recess, the protrusion and the flat portion are formed by:
patterning the overcoating layer using a mask, the mask including:
a transparent substrate that transmits light;
a translucent layer on the transparent substrate that transmits a portion of the light; and
a light blocking layer including:
a first pattern part corresponding to the first region to partially transmit the portion of the light having passed through the translucent layer; and
a second pattern part corresponding to the second region to diffract the portion of the light having passed through the translucent layer.

9. The method of claim 8, wherein a light transmittance of the translucent layer is about 25% to about 32%.

10. The method of claim 8, wherein the first pattern part has a plurality of first opening patterns, and a width of each of the first opening patterns is about 2 μm to about 5 μm.

11. The method of claim 8, wherein the second pattern part has a plurality of second opening patterns, and a width of each of the second opening patterns is about 1.0 μm to about 1.9 μm.

12. The method of claim 8, wherein a tight transmittance of the second pattern part is about 8% to about 12%.

13. A display panel comprising:
an array substrate including:
a pixel defined by gate and source lines, a transmission region and a reflection region being defined in the pixel;
an overcoating layer including:
a recess in the reflection region, the recess having a first height;
a protrusion in the reflection region, the protrusion having a second height greater than the first height; and
a flat portion in the transmission region, a height of the flat portion being between the first height and the second height, and
an opposite substrate combined with the array substrate.

14. The display panel of claim 13, wherein the array substrate further comprises:
a transparent electrode on the flat portion of the overcoating layer; and
a reflecting electrode on the recess and the protrusion.

15. The display panel of claim 13, wherein a liquid crystal layer is interposed between the array and opposite substrates.
